(19) United States
(12) Patent Application Publication
(10) Pub. No.: US 2025/0290807 A1
(43) Pub. Date: Sep. 18, 2025

(54) TEMPERATURE COEFFICIENT CALIBRATION OF RESISTOR THERMAL SENSORS

(71) Applicant: Taiwan Semiconductor Manufacturing Company, Ltd., Hsinchu (TW)

(72) Inventors: WEI-LIN LAI, Hsinchu City (TW); SZU-LIN LIU, Hsinchu City (TW)

(21) Appl. No.: 18/602,247

(22) Filed: Mar. 12, 2024

(51) Int. Cl. G01K 15/00; G01K 7/24; H01L 23/34; H01L 23/522

(52) U.S. Cl. CPC G01K 15/005; G01K 7/24; H01L 23/34; H01L 23/5228

(57) ABSTRACT

A method of calibrating a temperature coefficient of a thermal sensor. The method includes determining a resistance temperature coefficient function (RTCF) based on resistance measurements of resistors on a plurality of semiconductor die at a first temperature and temperature coefficients for the plurality of semiconductor die, measuring, by a measurement circuit, a resistance of a resistor on a semiconductor die at the first temperature, and determining, by a control circuit, a calibrated temperature coefficient of the semiconductor die based on the measured resistance of the resistor on the semiconductor die at the first temperature and the RTCF.

### BACKGROUND

Temperature sensors are used to measure gas, liquid, and solid thermal properties. These temperature sensors, also referred to as thermal sensors, track temperature changes and are intended for general as well as specific applications. One thermal sensor is a resistor thermal sensor that includes a resistor for tracking the temperature of the environment. In a resistor thermal sensor, the resistance value of a resistor changes as the temperature of the resistor changes. This resistance versus temperature relationship is repeatable over time and captured as a temperature coefficient of the resistor. In a positive temperature coefficient (PTC) thermal sensor, the resistance of the resistor increases as the temperature increases, and the resistance of the resistor decreases as the temperature decreases. In a negative temperature coefficient (NTC) thermal sensor, the resistance of the resistor decreases as the temperature increases, and the resistance of the resistor increases as the temperature decreases.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a semiconductor device, in accordance with some embodiments.

FIG. 2 is a diagram schematically illustrating a plot of an RTCF for resistance values of a resistor on a plurality of semiconductor die versus temperature coefficients for the plurality of semiconductor die, in accordance with some embodiments.

FIG. 3 is a diagram schematically illustrating a resistance value of the resistor on a newly added semiconductor die at 25 degrees centigrade, in accordance with some embodiments.

FIG. 4 is a diagram schematically illustrating the calibrated temperature coefficient for the resistance value of the resistor on the newly added semiconductor die, in accordance with some embodiments.

FIG. 5 is a diagram schematically illustrating a characteristic flowchart of the method of calibrating the temperature coefficient, in accordance with some embodiments.

FIG. 6 is a diagram schematically illustrating a BEOL resistor, in accordance with some embodiments.

FIG. 7 is a diagram schematically illustrating a measurement circuit, in accordance with some embodiments.

FIG. 8 is a diagram schematically illustrating a Wheatstone bridge circuit and a measurement circuit, in accordance with some embodiments.

FIG. 9 is a diagram schematically illustrating a plot of an RTCF for the ratio of the BEOL_R to the Hi_R (R_{M}/R_{H}) on a plurality of semiconductor die versus temperature coefficients for the plurality of semiconductor die, in accordance with some embodiments.

FIG. 10 is a diagram schematically illustrating a method of calibrating a temperature coefficient of a thermal sensor, in accordance with some embodiments.

FIG. 11 is a diagram schematically illustrating a method of measuring a temperature of a semiconductor die, in accordance with some embodiments.

FIG. 12 is a block diagram schematically illustrating an example of a computer system configured to provide the semiconductor devices and methods of the current disclosure, in accordance with some embodiments.

FIG. 13 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Disclosed embodiments provide resistor thermal sensors that include back-end-of-line (BEOL) resistors in BEOL resistor (BEOL_R) thermal sensors. Temperature coefficients are calibrated in a 1-point temperature coefficient calibration that reduces errors in the temperature readings.

In a conventional calibration method, the resistance value of a resistor on a die is obtained at room temperature for many dice and an average resistance value of the resistor is calculated from the measurements. Also, the temperature coefficients of the resistors are obtained for each of the dice and an average temperature coefficient is calculated to provide a reference temperature coefficient. The average temperature coefficient is determined from all the dice, such that the accuracy of the resistor thermal sensors is limited by process-induced global temperature coefficient variations of the resistors. The lot-to-lot resistance values of the resistors are not consistent and errors in temperature readings are affected by the process changes.

Disclosed embodiments include a method of calibrating a temperature coefficient of a resistor thermal sensor by determining a resistance temperature coefficient function (RTCF) of the resistance measurements of a resistor on a die for a plurality of semiconductor die at a first temperature and the temperature coefficients of the resistors. The method includes measuring the resistance value of the resistor on the die at the first temperature and determining a calibrated temperature coefficient of the die based on the measured resistance of the resistor on the die at the first temperature and the RTCF. In some embodiments, the calibrated temperature coefficient of a die is the average temperature coefficient of the resistors in the plurality of semiconductor die that have the same measured resistance value at the first temperature. Thus, the calibrated temperature coefficient variation considers the process variation from those dice that have the same measured resistance value at the first temperature and not the process variation from all the plurality of semiconductor die (as in the conventional method of calibrating the temperature coefficient).

In some embodiments, determining the RTCF includes determining a linear approximation function of the resistance measurements at the first temperature versus the temperature coefficients for the plurality of semiconductor die. In some embodiments, determining the RTCF includes determining a linear approximation function of Wheatstone bridge resistance measurements at the first temperature versus the temperature coefficients for the plurality of semiconductor die. In some embodiments, determining the RTCF includes determining the RTCF at a first temperature of 25 degrees centigrade. In some embodiments, the resistor on the die is a back-end-of-line (BEOL) resistor.

Disclosed embodiments, further include measuring the resistance of the resistor on the die at a second temperature and determining the second temperature based on the resistance of the resistor on the die at the second temperature and the calibrated temperature coefficient of the die.

Further disclosed embodiments include a semiconductor device that includes a resistor, a measurement circuit configured to measure resistance of the resistor at a first temperature, and a control circuit configured to determine a calibrated temperature coefficient of the resistor based on the measured resistance of the resistor at the first temperature and the RTCF. In some embodiments, the resistor is a BEOL resistor. In some embodiments, the measurement circuit is configured to measure the resistance of the resistor in a single resistance measurement. In some embodiments, the measurement circuit includes a Wheatstone bridge and the measurement circuit is configured to measure the resistance of the resistor using the Wheatstone bridge.

Advantages of the disclosed embodiments include reducing errors in temperature readings, no increase in calibration costs, and improved stability with process changes, including BEOL process changes. This improves the accuracy of BEOL_R thermal sensors without increasing calibration costs.

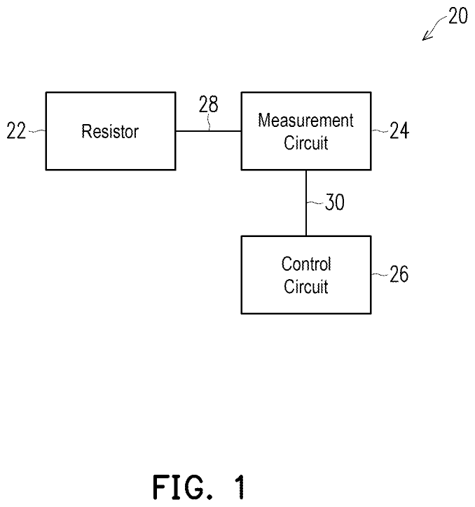

FIG. 1 is a diagram schematically illustrating a semiconductor device 20, in accordance with some embodiments of the disclosure. The semiconductor device 20 is a resistor thermal sensor. The semiconductor device 20 includes a resistor 22, a measurement circuit 24, and a control circuit 26. In some embodiments, the resistor 22, the measurement circuit 24, and the control circuit 26 are at least part of one semiconductor die. In some embodiments, each of the resistor 22, the measurement circuit 24, and the control circuit 26 is at least part of a different semiconductor die. In some embodiments, the resistor 22 and the measurement circuit 24 are at least part of one semiconductor die. In some embodiments, the control circuit 26 is at least part of a separate semiconductor die that is communicatively coupled to a semiconductor die that includes the measurement circuit 24. In some embodiments, a semiconductor die is an integrated circuit (IC).

The semiconductor device 20 includes at least one substrate (not shown) that includes active devices. The resistor 22 is situated over the substrate and, in some embodiments, the resistor is a BEOL_R that includes at least two metal layers. In some embodiments, the measurement circuit 24 is in the substrate and electrically connected to the resistor 22, where the measurement circuit 24 is configured to measure the resistance of the resistor 22.

The resistor 22 is electrically connected to the measurement circuit 24 via a conductive path 28, and the measurement circuit 24 is electrically connected to the control circuit 26 via a conductive path 30. In some embodiments, the resistor 22 is a BEOL resistor. In some embodiments, the semiconductor device 20 is a BEOL_R thermal sensor.

The measurement circuit 24 is configured to measure the resistance of the resistor 22. In some embodiments, the measurement circuit 24 is configured to measure the resistance of the resistor 22 in a single resistance measurement. In some embodiments, the measurement circuit 24 is connected to a Wheatstone bridge that includes multiple resistors and the measurement circuit 24 is configured to measure the resistance of the multiple resistors including the resistor 22 in the Wheatstone bridge.

The control circuit 26 is a computing system configured to execute code from memory, such as memory on-board the control circuit 26 or memory otherwise communicatively connected to the control circuit 26. The control circuit 26 can include one or more controllers and/or processors. In some embodiments, the control circuit 26 includes at least one controller and/or at least one processor communicatively connected to perform the functions of the semiconductor device 20.

In operation, the semiconductor device 20 is configured to calibrate the temperature coefficient of the resistor 22 on the semiconductor die. The measurement circuit 24 is configured to measure a resistance value, i.e., the resistance, of the resistor 22 at a first temperature. The control circuit 26 is configured to determine the calibrated temperature coefficient of the resistor 22 based on the measured resistance of the resistor 22 at the first temperature and a resistor temperature coefficient function (RTCF).

The RTCF is determined from resistance measurements of the resistors 22 on a plurality of semiconductor die at the first temperature and the temperature coefficients of the resistors 22 on the die. In some embodiments, the resistance measurements of the resistor 22 on the plurality of semiconductor die and the temperature coefficients of the resistors 22 on the die are obtained by a separate computer system and the results are stored in computer memory, such that the control circuit 26 stores the results in on-board memory or accesses the results from other communicatively connected memory. In some embodiments, the resistance measurements of the resistors 22 on the plurality of semiconductor die and the temperature coefficients of the resistors 22 on the die are obtained by computer system simulations and the results are stored in computer memory, such that the control circuit 26 either stores the results in on-board memory or accesses the results from other communicatively connected memory. In some embodiments, the control circuit 26 stores the RTCF in memory and accesses the RTCF to determine the calibrated temperature coefficient for the resistor 22 on a semiconductor die.

In some embodiments, determining the RTCF includes determining a linear approximation function of the resistance measurements of the resistors on the plurality of semiconductor die at the first temperature versus the temperature coefficients for the plurality of semiconductor die. In some embodiments, determining the RTCF includes determining a linear approximation function of Wheatstone bridge resistance measurements of the resistors on the plurality of semiconductor die at the first temperature versus the temperature coefficients for the plurality of semiconductor die. In some embodiments, determining the RTCF includes determining the RTCF at a first temperature of 25 degrees centigrade.

In further operation, the semiconductor device 20 is configured to determine the temperature of the semiconductor device 20 and/or the surrounding environment. The measurement circuit 24 is configured to measure the resistance of the resistor 22 at a second temperature and the control circuit 26 is configured to determine the second temperature based on the resistance of the resistor 22 at the second temperature and the calibrated temperature coefficient of the resistor 22 on the die.

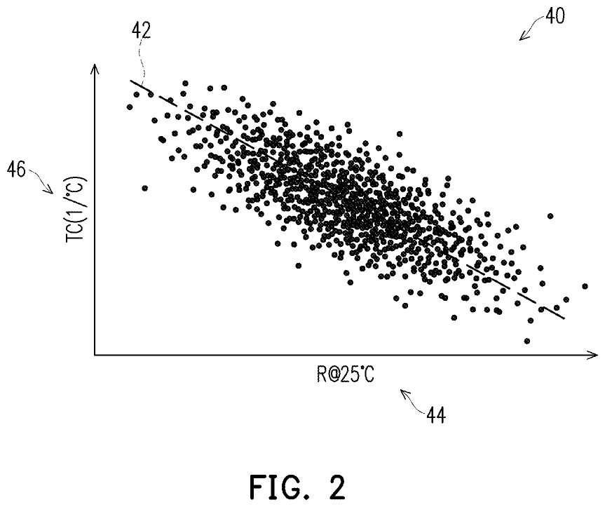

FIGS. 2-4 are diagrams schematically illustrating calibrating the temperature coefficient of the resistor 22 on the semiconductor die, in accordance with some embodiments of the disclosure.

FIG. 2 is a diagram schematically illustrating a plot 40 of an RTCF 42 for resistance values of a resistor 22 on a plurality of semiconductor die versus temperature coefficients for the plurality of semiconductor die, in accordance with some embodiments of the disclosure. The resistance values are obtained at 25 degrees centigrade. The plot 40 includes the resistance values R at 25 degrees centigrade on the x-axis 44 and the temperature coefficients (TCs) per degree centigrade on the y-axis 46. Each dot in the plot 40 represents a resistance value of a resistor 22 on a semiconductor die versus a temperature coefficient for the resistor 22 on that semiconductor die.

The RTCF is a linear approximation function, such as an average value line, of the resistance values for the plurality of semiconductor die at the first temperature, i.e., at 25 degrees centigrade, versus the temperature coefficients for the plurality of semiconductor die. In some embodiments, resistance measurements of the resistor 22 on the plurality of semiconductor die and the temperature coefficients of the resistor 22 are obtained by a separate computer system and the results are stored in computer memory. In some embodiments, the resistance values of the resistor 22 on the plurality of semiconductor die and the temperature coefficients of the resistor 22 are obtained by computer system simulations and the results are stored in computer memory. In either situation, the control circuit 26 stores the results in on-board memory or accesses the results from other communicatively connected memory. In some embodiments, the control circuit 26 stores the RTCF in memory and accesses the RTCF to determine the calibrated temperature coefficient for the resistor 22 on the die.

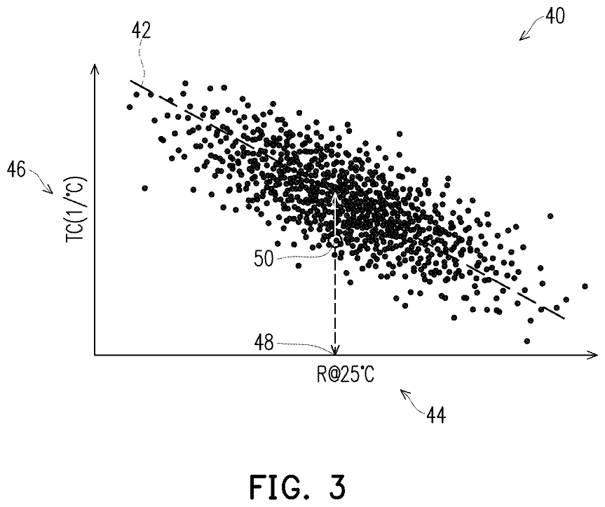

FIG. 3 is a diagram schematically illustrating a resistance value 48 of the resistor 22 on a newly added semiconductor die 50 at 25 degrees centigrade, in accordance with some embodiments of the disclosure. The measured resistance value 48 of the resistor 22 on the newly added semiconductor die 50 is plotted along the x-axis 44 of the plot 40. The measurement circuit 24 is configured to measure the resistance value 48 of the resistor 22 on the newly added semiconductor die 50 at 25 degrees centigrade.

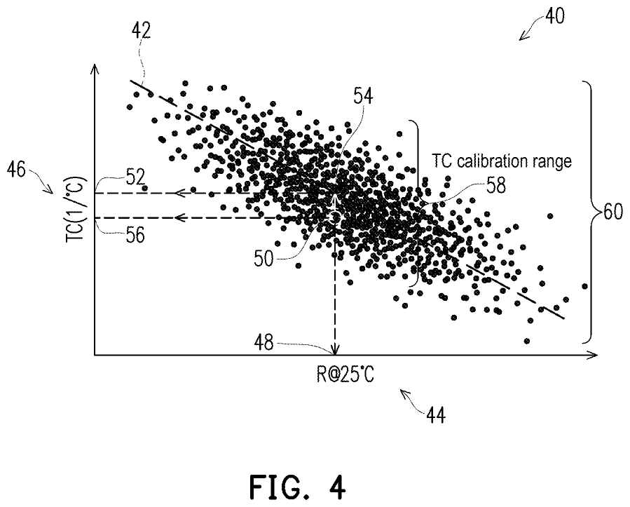

FIG. 4 is a diagram schematically illustrating the calibrated temperature coefficient 52 for the resistance value 48 of the resistor 22 on the newly added semiconductor die 50, in accordance with some embodiments of the disclosure. The calibrated temperature coefficient 52 is obtained by intersecting the measured resistance value 48 with the RTCF 42. The intersection 54 of the measured resistance value 48 with the RTCF 42 is traced to the y-axis 46 to obtain the calibrated temperature coefficient 52. By way of example, a hypothetical measured temperature coefficient 56 for the newly added semiconductor die 50 is plotted along the y-axis 46 to illustrate the difference between the calibrated temperature coefficient 52 and a measured temperature coefficient 56. The control circuit 26 is configured to determine the calibrated temperature coefficient 52 of the resistor 22 for the newly added semiconductor die 50 based on the measured resistance value 48 of the resistor 22 at 25 degrees centigrade and the RTCF 42.

The calibrated temperature coefficient 52 is obtained from the measured resistance value 48 and the RTCF 42, such that the calibrated temperature coefficient 52 is the average temperature coefficient for all the resistors 22 with the same measured resistance value 48 in the plurality of semiconductor die that were used to create the RTCF 42. This temperature coefficient calibration range 58 is much smaller than the temperature coefficient range 60 of all the plurality of semiconductor die that were used to create the RTCF 42 (which would otherwise be used in a conventional calibration method). Thus, the calibrated temperature coefficients of the present disclosure have a smaller temperature coefficient variation.

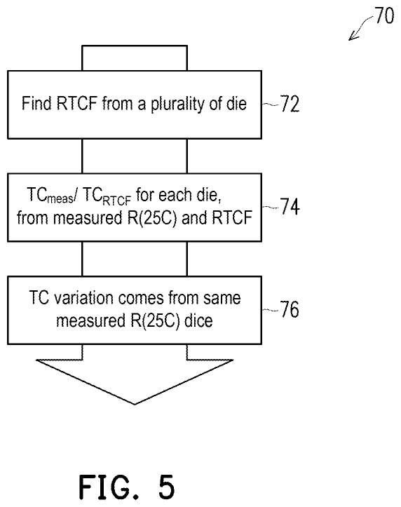

FIG. 5 is a diagram schematically illustrating a characteristic flowchart 70 of the method of calibrating the temperature coefficient, in accordance with some embodiments of the disclosure. At block 72, the method includes finding a RTCF from the plurality of semiconductor die. In some embodiments, the RTCF is a linear approximation function, such as an average value line, of the resistance values for the plurality of semiconductor die at a first temperature, such as 25 degrees centigrade, versus the temperature coefficients for the plurality of semiconductor die. In some embodiments, the resistance measurements of the resistor 22 on the plurality of semiconductor die and the temperature coefficients of the resistor 22 are obtained by a separate computer system and the results are stored in computer memory. In some embodiments, the resistance values of the resistor 22 on the plurality of semiconductor die and the temperature coefficients of the resistor 22 are obtained by computer system simulations and the results are stored in computer memory. In both situations, the control circuit 26 stores the results in on-board memory or accesses the results from other communicatively connected memory. The control circuit 26 further accesses the RTCF to determine the calibrated temperature coefficient for the resistor 22 on the die.

At block 74, the hypothetical measured temperature coefficient (TCₘₑₐₛ) 56 for the newly added semiconductor die 50 is compared to the calibrated temperature coefficient (TC_{RTCF}) 52. The ratio of TCₘₑₐₛ/TC_{RTCF} is determined for each newly added semiconductor die and is an indication of the difference between the calibrated temperature coefficient (TC_{RTCF}) 52 and the measured temperature coefficient (TCₘₑₐₛ) 56.

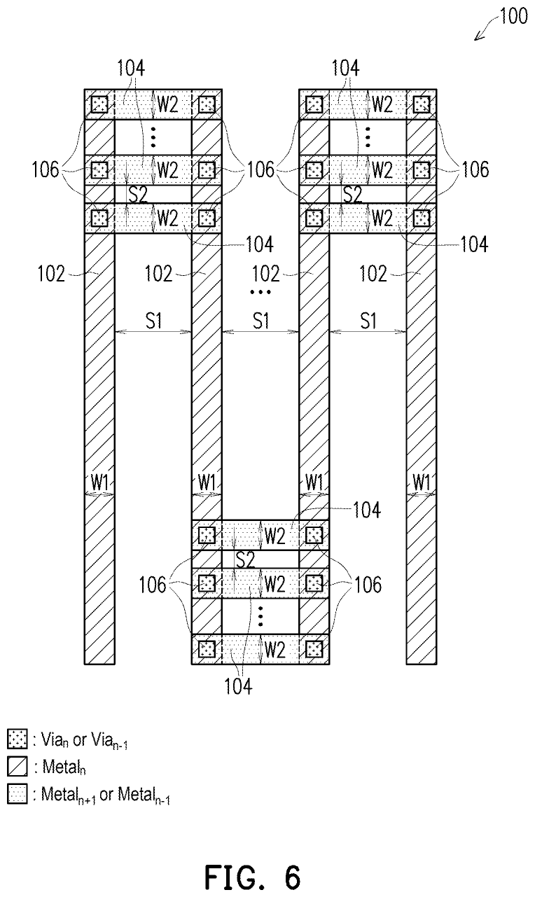

At block 76, the calibrated temperature coefficient 52 is obtained from the measured resistance value 48 and the RTCF 42, such that the calibrated temperature coefficient 52 is the average temperature coefficient for all the resistors 22 with the same measured resistance value 48 in the plurality of semiconductor die that were used to create the RTCF 42. The temperature coefficient variation comes from the semiconductor dice with the same measured resistance value 48. The temperature coefficient range 58 for the semiconductor dice with the same measured resistance value 48 is much smaller than the temperature coefficient range 60 for all the plurality of semiconductor die that were used to create the RTCF 42. Thus, the calibrated temperature coefficients of the present disclosure have a smaller temperature coefficient variation. In some embodiments, the temperature coefficient standard deviation is equal to the standard deviation of [(TCₘₑₐₛ for each die−TC_{RTCF} for each die)/TC_{RTCF} for each die]. FIG. 6 is a diagram schematically illustrating a BEOL resistor 100, in accordance with some embodiments of the disclosure. The BEOL resistor 100 is part of a thermal sensor, such as a BEOL_R thermal sensor. In some embodiments, the resistor 22 in the semiconductor device 20 of FIG. 1 is like the BEOL resistor 100. The BEOL resistor 100 includes first metal lines Metalₙ 102, second metal lines Metalₙ₊₁(or Metalₙ₋₁) 104 and connecting vias viaₙ (or viaₙ₋₁) 106. The second metal lines Metalₙ₊₁ (or Metalₙ₋₁) 104 are links between the first metal lines Metalₙ 102 with the connecting vias viaₙ (or viaₙ₋₁) 106 connecting the first metal lines Metalₙ 102 to the second metal lines Metalₙ₊₁ (or Metalₙ₋₁) 104. The BEOL resistor 100 is formed on a substrate situated under the first metal lines Metalₙ 102, the second metal lines Metalₙ₊₁ (or Metalₙ₋₁) 104, and the connecting vias viaₙ (or viaₙ₋₁) 106. W1 is the width of the first metal lines Metalₙ 102 and S1 is the spacing between the first metal lines Metalₙ 102. W2 is the width of the second metal lines Metalₙ₊₁ (or Metalₙ₋₁) 104 and S2 is the spacing between the second metal lines Metalₙ₊₁ (or Metalₙ₋₁) 104. In some embodiments, the distribution of the resistance values of the BEOL resistor 100 on a plurality of semiconductor die and the temperature coefficients of the BEOL resistor 100 on the plurality of semiconductor die is like the distribution illustrated in FIG. 2.

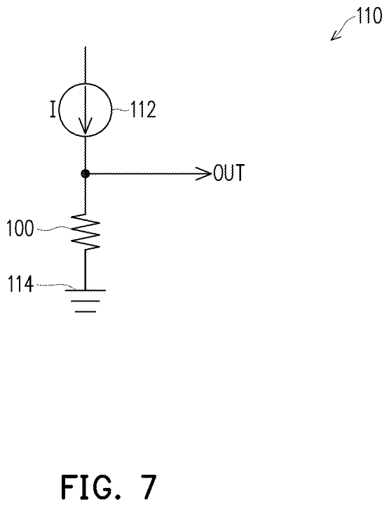

FIG. 7 is a diagram schematically illustrating a measurement circuit 110, in accordance with some embodiments of the disclosure. The measurement circuit 110 is part of a thermal sensor, such as a BEOL_R thermal sensor. In some embodiments, the measurement circuit 24 in the semiconductor device 20 of FIG. 1 is like the measurement circuit 110.

The measurement circuit 110 includes a current source 112 connected to the resistor 100. One end of the resistor 100 is connected to the current source 112 and another end of the resistor 100 is connected to a reference 114, such as ground. The current I of the current source 112 passes through the resistor 100 to provide a voltage at the output OUT that is converted into a resistance value for the resistor 100. In some embodiments, the measurement circuit 110 is configured to convert the voltage at the output OUT into the resistance value of the resistor 100. In some embodiments, the control circuit 26 is configured to convert the voltage at the output OUT into the resistance value of the resistor 100.

The control circuit 26 determines the calibrated temperature coefficient of the resistor 100 based on the measured resistance of the resistor 100 at the first temperature, such as 25 degrees centigrade, and the RTCF. Also, the measurement circuit 24 measures the resistance of the resistor 100 at a second temperature and the control circuit 26 determines the second temperature based on the measured resistance of the resistor 100 at the second temperature and the calibrated temperature coefficient of the resistor 100.

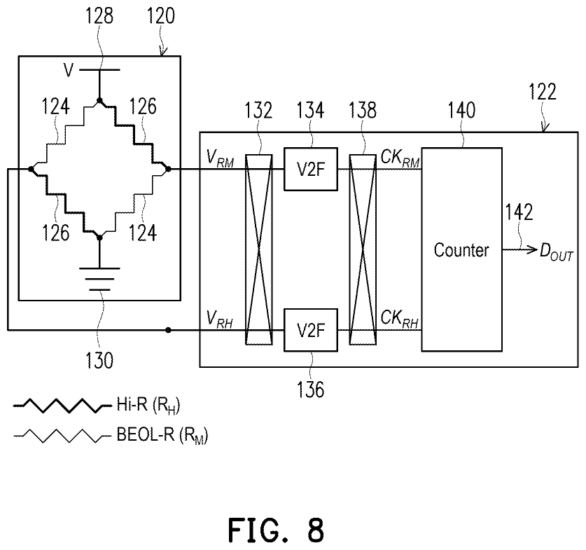

FIG. 8 is a diagram schematically illustrating a Wheatstone bridge circuit 120 and a measurement circuit 122, in accordance with some embodiments. The Wheatstone bridge circuit 120 and the measurement circuit 122 are part of a thermal sensor, such as a BEOL_R thermal sensor. In some embodiments, the resistor 22 in the semiconductor device 20 of FIG. 1 is like the Wheatstone bridge circuit 120. In some embodiments, the measurement circuit 24 in the semiconductor device 20 of FIG. 1 is like the measurement circuit 122.

The Wheatstone bridge circuit 120 includes two BEOL_Rs (R_{M}) 124 and two high resistors (Hi_R) (R_{H}) 126. A power source 128 provides a voltage V and is electrically connected to one end of a first BEOL_R (R_{M}) 124 and to one end of a first Hi_R (R_{H}) 126. The other end of the first BEOL_R (R_{M}) 124 is electrically connected to one end of a second Hi_R (R_{H}) 126 and the other end of the first Hi_R (R_{H}) 126 is electrically connected to one end of a second BEOL_R (R_{M}) 124. The other ends of the second Hi_R (R_{H}) 126 and the second BEOL_R (R_{M}) 124 are electrically connected to a reference 130, such as ground. One output of the Wheatstone bridge circuit 120 at the intersection of the first Hi_R (R_{H}) 126 and the second BEOL_R (R_{M}) 124 provides a voltage V_{RM} and another output of the Wheatstone bridge circuit 120 at the intersection of the first BEOL_R (R_{M}) 124 and the second Hi_R (R_{H}) 126 provides a voltage V_{RH}.

The measurement circuit 122 includes a first chopper circuit 132 that receives the voltage V_{RM} and the voltage V_{RH}. The first chopper circuit 132 is electrically connected to a first voltage-to-frequency (V2F) converter 134 and a second V2F converter 136, which are electrically connected to a second chopper circuit 138. The first and second chopper circuits 132 and 138 are configured to remove voltage offsets in the measurement circuit 122. The measurement circuit 122 further includes the second chopper circuit 138 electrically connected to a counter 140 that has an output 142 that provides a digital output signal Dour of or related to the resistance values of the two BEOL_Rs (R_{M}) 124 and the two high resistors (Hi_R) (R_{H}) 126.

In operation, the measurement circuit 122 receives the BEOL_R voltage V_{RM} and the Hi_R voltage V_{RH} and the first chopper circuit 132 chops the received signals to remove offset voltage. The chopped signals are received by the first V2F converter 134 and the second V2F converter 136, which converts the voltage signals into clock signals. The second chopper circuit 138 receives the clock signals and chops the signals to remove offset voltage. The clock signals CK_{RM} and CK_{RH} are provided to the counter 140 that provides the digital output signal D_{OUT} to the control circuit 26 of FIG. 1.

The control circuit 26 determines the calibrated temperature coefficient of the ratio of the BEOL_R 124 to the Hi_R 126 (R_{M}/R_{H}) based on the measured resistance values of the BEOL_Rs (R_{M}) 124 and the high resistors (Hi_R) (R_{H}) 126 at the first temperature, such as 25 degrees centigrade, and an RTCF of the Wheatstone bridge resistance ratio R_{M}/R_{H}. Also, the measurement circuit 122 measures the resistance values of the BEOL_Rs (R_{M}) 124 and the high resistors (Hi_R) (R_{H}) 126 at a second temperature and the control circuit 26 determines the second temperature based on the measured resistance values of the BEOL_Rs (R_{M}) 124 and the high resistors (Hi_R) (R_{H}) 126 at the second temperature and the calibrated temperature coefficient of the ratio of the BEOL_R 124 to the Hi_R 126 (R_{M}/R_{H}).

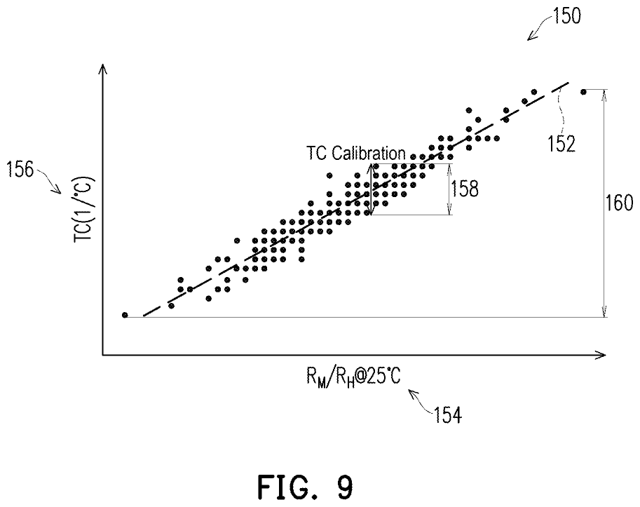

FIG. 9 is a diagram schematically illustrating a plot 150 of an RTCF 152 for the ratio of the BEOL_R 124 to the Hi_R 126 (R_{M}/R_{H}) on a plurality of semiconductor die versus temperature coefficients for the plurality of semiconductor die, in accordance with some embodiments of the disclosure. The resistance values are obtained at 25 degrees centigrade. The plot 150 includes the ratios RM/RH at 25 degrees centigrade on the x-axis 154 and the TCs per degree centigrade on the y-axis 156. Each dot in the plot 150 represents a ratio RM/RH on a semiconductor die versus a temperature coefficient for the ratio RM/RH on that semiconductor die.

The RTCF is a linear approximation function, such as an average value line, of the resistance value ratio RM/RH for the plurality of semiconductor die at the first temperature, i.e., at 25 degrees centigrade, versus the temperature coefficients for the plurality of semiconductor die. In some embodiments, resistance measurements for the ratio RM/RH on the plurality of semiconductor die and the temperature coefficients for the ratio RM/RH are obtained by a separate computer system and the results are stored in computer memory. In some embodiments, the resistance values for the ratio RM/RH on the plurality of semiconductor die and the temperature coefficients for the ratio RM/RH are obtained by computer system simulations and the results are stored in computer memory. In either situation, the control circuit 26 stores the results in on-board memory or accesses the results from other communicatively connected memory. In some embodiments, the control circuit 26 stores the RTCF in memory and accesses the RTCF to determine the calibrated temperature coefficient for the ratio R_{M}/R_{H} on a die.

The calibrated temperature coefficient is obtained from the measured resistance ratio RM/RH of a die and the RTCF 152, such that the calibrated temperature coefficient is the average temperature coefficient for all the resistors with the same measured resistance ratio RM/RH in the plurality of semiconductor die that were used to create the RTCF 152. The temperature coefficient calibration range 158, for example, is much smaller than the temperature coefficient range 160 of all the plurality of semiconductor die that were used to create the RTCF 152 (that may otherwise be used in a conventional calibration method). Thus, the calibrated temperature coefficients of the present disclosure have a smaller temperature coefficient variation.

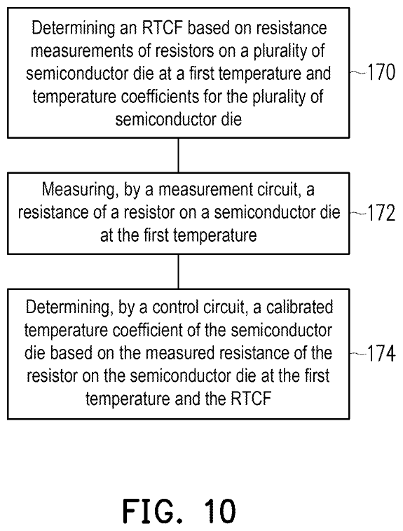

FIG. 10 is a diagram schematically illustrating a method of calibrating a temperature coefficient of a thermal sensor, in accordance with some embodiments of the disclosure. The thermal sensor is a resistor thermal sensor, such as a BEOL_R thermal sensor. In some embodiments, each thermal sensor includes a single resistor. In some embodiments, each thermal sensor includes multiple resistors in a Wheatstone bridge. In some embodiments, the thermal sensor is like semiconductor device 20 of FIG. 1.

At step 170, the method includes determining an RTCF based on resistance measurements of resistors on a plurality of semiconductor die at a first temperature and temperature coefficients for the plurality of semiconductor die. In some embodiments, determining the RTCF includes determining a linear approximation function of the resistance measurements at the first temperature and the temperature coefficients for the plurality of semiconductor die. In some embodiments, determining the RTCF includes determining a linear approximation function of Wheatstone bridge resistance measurements at the first temperature and the temperature coefficients for the plurality of semiconductor die. In some embodiments, determining the RTCF includes determining the RTCF at a first temperature of 25 degrees centigrade.

At step 172, the method includes measuring, by a measurement circuit, a resistance of one or more resistors on a semiconductor die at the first temperature. In some embodiments, the one or more resistors on the die include one or more BEOL resistors and, in some embodiments, the one or more BEOL resistors each include at least two metal layers. In some embodiments, measuring the resistance of the one or more resistors on the die includes measuring the resistance of one or more resistors on the die in a single resistance measurement and, in some embodiments, measuring the resistance of the one or more resistors on the die includes measuring the resistance of the one or more resistors on the die using a Wheatstone bridge.

At step 174, the method includes determining, by a control circuit, a calibrated temperature coefficient of the semiconductor die based on the measured resistance of the one or more resistors on the semiconductor die at the first temperature and the RTCF. Further, in some embodiments, the method includes determining a measured temperature coefficient of the semiconductor die for the measured resistance of the one or more resistors on the semiconductor die at the first temperature and determining a ratio of the measured temperature coefficient of the semiconductor die to the calibrated temperature coefficient of the semiconductor die.

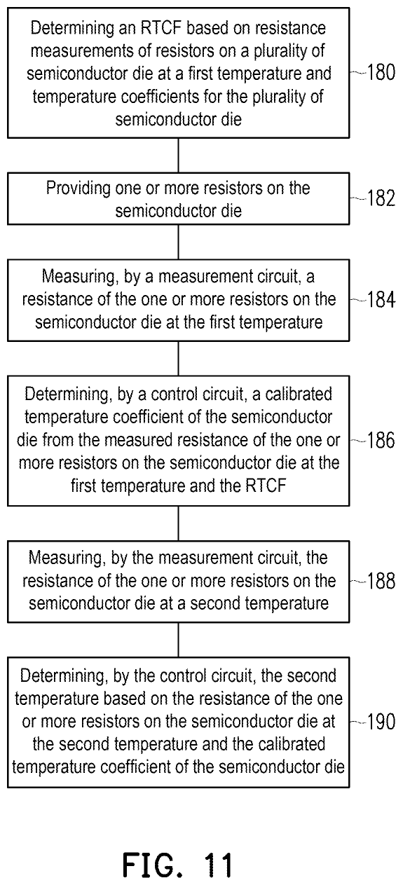

FIG. 11 is a diagram schematically illustrating a method of measuring a temperature of a semiconductor die, in accordance with some embodiments of the disclosure. The temperature of the semiconductor die is measured with a thermal sensor, such as a resistor thermal sensor, on the semiconductor die. In some embodiments, the resistor thermal sensor includes one or more BEOL_Rs in a BEOL_R thermal sensor. In some embodiments, each thermal sensor includes a single resistor. In some embodiments, each thermal sensor includes multiple resistors in a Wheatstone bridge. In some embodiments, the thermal sensor is like semiconductor device 20 of FIG. 1.

At step 180, the method includes determining an RTCF based on resistance measurements of resistors on a plurality of semiconductor die at a first temperature and temperature coefficients for the plurality of semiconductor die. In some embodiments, determining the RTCF includes determining a linear approximation function of the resistance measurements at the first temperature and the temperature coefficients for the plurality of semiconductor die. In some embodiments, determining the RTCF includes determining a linear approximation function of Wheatstone bridge resistance measurements at the first temperature and the temperature coefficients for the plurality of semiconductor die. In some embodiments, determining the RTCF includes determining the RTCF at a first temperature of 25 degrees centigrade.

At step 182, the method includes providing one or more resistors on the semiconductor die. In some embodiments, the one or more resistors on the semiconductor die include one or more BEOL_Rs.

At step 184, the method includes measuring, by a measurement circuit, a resistance of the one or more resistors on the semiconductor die at the first temperature. In some embodiments, the method includes measuring the resistance of the one or more resistors on the semiconductor die in a single resistance measurement. In some embodiments, the method includes measuring the resistance of the one or more resistors on the semiconductor die using a Wheatstone bridge.

At step 186, the method includes determining, by a control circuit, a calibrated temperature coefficient of the semiconductor die from the measured resistance of the one or more resistors on the semiconductor die at the first temperature and the RTCF.

At step 188, the method includes measuring, by the measurement circuit, the resistance of the one or more resistors on the semiconductor die at a second temperature and, at step 190, the method includes determining, by the control circuit, the second temperature based on the resistance of the one or more resistors on the semiconductor die at the second temperature and the calibrated temperature coefficient of the semiconductor die.

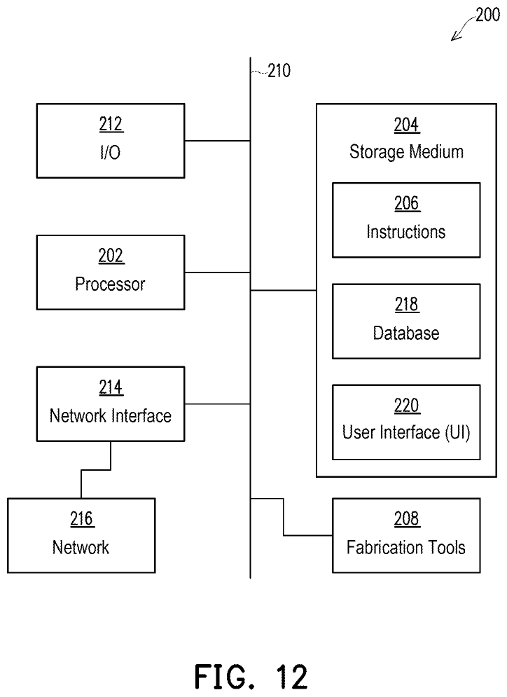

FIG. 12 is a block diagram schematically illustrating an example of a computer system 200 configured to provide the semiconductor devices and methods of the current disclosure, in accordance with some embodiments. Some or all the design, layout, and manufacture of the semiconductor devices, also referred to as semiconductor circuits, can be performed by or with the computer system 200. Also, some or all the resistance measurements, temperature coefficient determinations, and RTCF determinations can be performed with the aid of the computer system 200. In some embodiments, the computer system 200 includes an electronic design automation (EDA) system. In some embodiments, the semiconductor devices are ICs.

In some embodiments, the system 200 is a general-purpose computing device including a processor 202 and a non-transitory, computer-readable storage medium 204. The computer-readable storage medium 204 may be encoded with, e.g., store, computer program code such as executable instructions 206. Execution of the instructions 206 by the processor 202 provides (at least in part) a design tool that implements a portion or all the functions of the system 200, such as pre-layout simulations, post-layout simulations, routing, rerouting, and final layout for manufacturing. Further, fabrication tools 208 are included to further layout and physically implement the design and manufacture of the semiconductor devices. In some embodiments, execution of the instructions 206 by the processor 202 provides (at least in part) a design tool that implements a portion or all the functions of the system 200. In some embodiments, the system 200 includes a commercial router. In some embodiments, the system 200 includes an automatic place and route (APR) system.

The processor 202 is electrically coupled to the computer-readable storage medium 204 by a bus 210 and to an I/O interface 212 by the bus 210. A network interface 214 is also electrically connected to the processor 202 by the bus 210. The network interface 214 is connected to a network 216, so that the processor 202 and the computer-readable storage medium 204 can connect to external elements using the network 216. The processor 202 is configured to execute the computer program code or instructions 206 encoded in the computer-readable storage medium 204 to cause the system 200 to perform a portion or all the functions of the system 200, such as providing the semiconductor devices and methods of the current disclosure and other functions of the system 200. In some embodiments, the processor 202 is a central processing unit (CPU), a multi-processor, a distributed processing system, an application specific integrated circuit (ASIC), and/or a suitable processing unit.

In some embodiments, the computer-readable storage medium 204 is an electronic, magnetic, optical, electromagnetic, infrared, and/or semiconductor system or apparatus or device. For example, the computer-readable storage medium 204 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 204 can include a compact disk read only memory (CD-ROM), a compact disk read/write memory (CD-R/W), and/or a digital video disc (DVD).

In some embodiments, the computer-readable storage medium 204 stores computer program code or instructions 206 configured to cause the system 200 to perform a portion or all the functions of the system 200. In some embodiments, the computer-readable storage medium 204 also stores information which facilitates performing a portion or all the functions of the system 200. In some embodiments, the computer-readable storage medium 204 stores a database 218 that includes one or more of component libraries, digital circuit cell libraries, and databases.

The system 200 includes the I/O interface 212, which is coupled to external circuitry. In some embodiments, the I/O interface 212 includes a keyboard, keypad, mouse, trackball, trackpad, touchscreen, and/or cursor direction keys for communicating information and commands to the processor 202.

The network interface 214 is coupled to the processor 202 and allows the system 200 to communicate with the network 216, to which one or more other computer systems are connected. The network interface 214 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 200 can be performed in two or more systems that are like system 200.

The system 200 is configured to receive information through the I/O interface 212. The information received through the I/O interface 212 includes one or more of instructions, data, design rules, libraries of components and cells, and/or other parameters for processing by the processor 202. The information is transferred to the processor 202 by the bus 210. Also, the system 200 is configured to receive information related to a user interface (UI) through the I/O interface 212. This UI information can be stored in the computer-readable storage medium 204 as a UI 220.

In some embodiments, a portion or all the functions of the system 200 are implemented via a standalone software application for execution by a processor. In some embodiments, a portion or all the functions of the system 200 are implemented in a software application that is a part of an additional software application. In some embodiments, a portion or all the functions of the system 200 are implemented as a plug-in to a software application. In some embodiments, at least one of the functions of the system 200 is implemented as a software application that is a portion of an EDA tool. In some embodiments, a portion or all the functions of the system 200 are implemented as a software application that is used by the system 200. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 200 include fabrication tools 208 for implementing the manufacturing processes of the system 200. For example, based on the final layout, photolithographic masks may be generated, which are used to fabricate the semiconductor device by the fabrication tools 208.

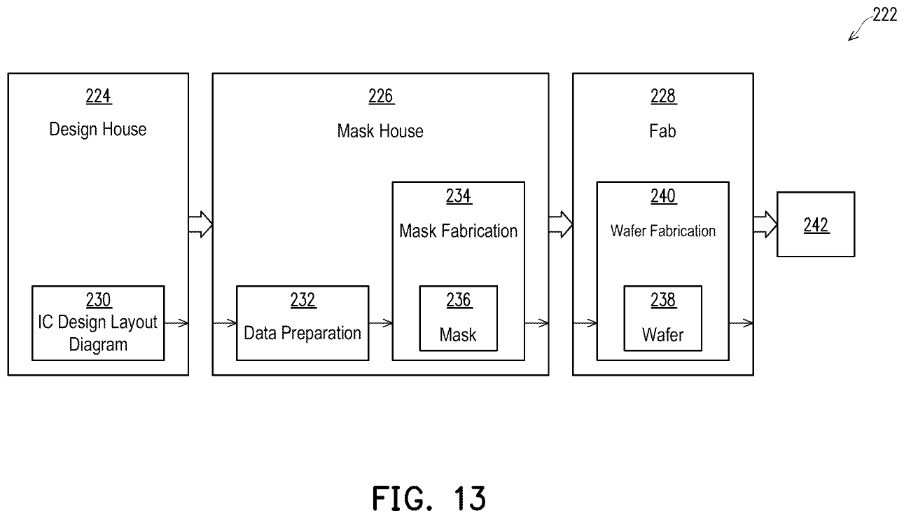

Further aspects of device fabrication are disclosed in conjunction with FIG. 13, which is a block diagram of a semiconductor device manufacturing system 222 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 222.

In FIG. 13, the semiconductor device manufacturing system 222 includes entities, such as a design house 224, a mask house 226, and a semiconductor device manufacturer/fabricator (“Fab”) 228, that interact with one another in the design, development, and manufacturing cycles and/or services related to manufacturing a semiconductor device, such as the semiconductor devices described herein. The entities in the system 222 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 224, the mask house 226, and the semiconductor device fab 228 are owned by a single larger company. In some embodiments, two or more of the design house 224, the mask house 226, and the semiconductor device fab 228 coexist in a common facility and use common resources.

The design house (or design team) 224 generates a semiconductor device design layout diagram 230. The semiconductor device design layout diagram 230 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 230 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 224 implements a design procedure to form a semiconductor device design layout diagram 230. The semiconductor device design layout diagram 230 is presented in one or more data files having information of the geometrical patterns. For example, semiconductor device design layout diagram 230 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 226 includes data preparation 232 and mask fabrication 234. The mask house 226 uses the semiconductor device design layout diagram 230 to manufacture one or more masks 236 to be used for fabricating the various layers of the semiconductor device or semiconductor structure. The mask house 226 performs mask data preparation 232, where the semiconductor device design layout diagram 230 is translated into a representative data file (RDF). The mask data preparation 232 provides the RDF to the mask fabrication 234. The mask fabrication 234 includes a mask writer that converts the RDF to an image on a substrate, such as a mask (reticle) 236 or a semiconductor wafer 238. The design layout diagram 230 is manipulated by the mask data preparation 232 to comply with characteristics of the mask writer and/or criteria of the semiconductor device fab 228. In FIG. 13, the mask data preparation 232 and the mask fabrication 234 are illustrated as separate elements. In some embodiments, the mask data preparation 232 and the mask fabrication 234 can be collectively referred to as mask data preparation.

In some embodiments, the mask data preparation 232 includes an optical proximity correction (OPC) which uses lithography enhancement techniques to compensate for image errors, such as those that can arise from diffraction, interference, other process effects and the like. The OPC adjusts the semiconductor device design layout diagram 230. In some embodiments, the mask data preparation 232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 232 includes a mask rule checker (MRC) that checks the semiconductor device design layout diagram 230 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 230 to compensate for limitations during the mask fabrication 234, which may undo part of the modifications performed by OPC to meet mask creation rules.

In some embodiments, the mask data preparation 232 includes lithography process checking (LPC) that simulates processing that will be implemented by the semiconductor device fab 228. LPC simulates this processing based on the semiconductor device design layout diagram 230 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are to be repeated to further refine the semiconductor device design layout diagram 230.

The above description of mask data preparation 232 has been simplified for the purposes of clarity. In some embodiments, data preparation 232 includes additional features such as a logic operation (LOP) to modify the semiconductor device design layout diagram 230 according to manufacturing rules. Additionally, the processes applied to the semiconductor device design layout diagram 230 during data preparation 232 may be executed in a variety of different orders.

After the mask data preparation 232 and during the mask fabrication 234, a mask 236 or a group of masks 236 are fabricated based on the modified semiconductor device design layout diagram 230. In some embodiments, the mask fabrication 234 includes performing one or more lithographic exposures based on the semiconductor device design layout diagram 230. In some embodiments, an electron-beam (e-beam) or a mechanism of multiple e-beams is used to form a pattern on a mask (photomask or reticle) 236 based on the modified semiconductor device design layout diagram 230. The mask 236 can be formed in various technologies. In some embodiments, the mask 236 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 236 includes a transparent substrate (e.g., fused quartz) and an opaque material (e.g., chromium) coated in the opaque regions of the binary mask. In another example, the mask 236 is formed using a phase shift technology. In a phase shift mask (PSM) version of the mask 236, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 234 is used in a variety of processes. For example, such a mask(s) is used in an ion implantation process to form various doped regions in the semiconductor wafer 238, in an etching process to form various etching regions in the semiconductor wafer 238, and/or in other suitable processes.

The semiconductor device fab 228 includes wafer fabrication 240. The semiconductor device fab 228 is a semiconductor device fabrication business that includes one or more manufacturing facilities for the fabrication of a variety of different semiconductor device products. In some embodiments, the semiconductor device fab 228 is a semiconductor foundry. For example, there may be a manufacturing facility for the front end of line (FEOL) fabrication of a plurality of semiconductor device products, while a second manufacturing facility may provide the BEOL fabrication for the interconnection and packaging of the semiconductor device products, and a third manufacturing facility may provide other services for the foundry business.

The semiconductor device fab 228 uses the mask(s) 236 fabricated by the mask house 226 to fabricate the semiconductor structures or semiconductor devices 242 of the current disclosure. Thus, the semiconductor device fab 228 at least indirectly uses the semiconductor device design layout diagram 230 to fabricate the semiconductor structures or semiconductor devices 242 of the current disclosure. Also, the semiconductor wafer 238 includes a silicon substrate or other proper substrate having material layers formed thereon, and the semiconductor wafer 238 further includes one or more of various doped regions, dielectric features, multilevel interconnects, and the like (formed at subsequent manufacturing steps). In some embodiments, the semiconductor wafer 238 is fabricated by the semiconductor device fab 228 using the mask(s) 236 to form the semiconductor structures or semiconductor devices 242 of the current disclosure. In some embodiments, the semiconductor device fabrication includes performing one or more lithographic exposures based at least indirectly on the semiconductor device design layout diagram 230.

Disclosed embodiments provide resistor thermal sensors that include BEOL resistors in BEOL_R thermal sensors. Temperature coefficients are calibrated in a 1-point temperature coefficient calibration that reduces errors in the temperature readings. Methods of calibrating a temperature coefficient of a resistor thermal sensor include determining an RTCF of resistance measurements of resistors on a plurality of semiconductor die at a first temperature and the temperature coefficients of the resistors, measuring the resistance value of a resistor on a die at the first temperature, and determining a calibrated temperature coefficient of the die based on the measured resistance value of the resistor on the die at the first temperature and the RTCF. In some embodiments, the calibrated temperature coefficient of the die is the average temperature coefficient of the resistors in the plurality of semiconductor die that have the same measured resistance value at the first temperature. In some embodiments, determining the RTCF includes determining a linear approximation function of the resistance measurements at the first temperature versus the temperature coefficients for the plurality of semiconductor die. In some embodiments, determining the RTCF includes determining a linear approximation function of Wheatstone bridge resistance measurements at the first temperature versus the temperature coefficients for the plurality of semiconductor die.

Disclosed embodiments include a semiconductor device that includes a resistor, a measurement circuit configured to measure resistance values of resistors at a first temperature, and a control circuit configured to determine a calibrated temperature coefficient of the resistors based on the measured resistance values of the resistors at the first temperature and the RTCF.

Further disclosed embodiments include measuring the resistance of the resistor on the die at a second temperature and determining the second temperature based on the resistance of the resistor on the die at the second temperature and the calibrated temperature coefficient of the die.

Advantages of the disclosed embodiments include reducing errors in temperature readings, no increase in calibration costs, and improved stability with process changes, including BEOL process changes. This improves the accuracy of BEOL_R thermal sensors without increasing calibration costs.

In accordance with some embodiments, a method of calibrating a temperature coefficient of a thermal sensor includes determining a resistance temperature coefficient function (RTCF) based on resistance measurements of resistors on a plurality of semiconductor die at a first temperature and temperature coefficients for the plurality of semiconductor die, measuring, by a measurement circuit, a resistance of a resistor on a semiconductor die at the first temperature, and determining, by a control circuit, a calibrated temperature coefficient of the semiconductor die based on the measured resistance of the resistor on the semiconductor die at the first temperature and the RTCF.

In accordance with further embodiments, a method of measuring a temperature of a semiconductor die includes determining an RTCF based on resistance measurements of resistors on a plurality of semiconductor die at a first temperature and temperature coefficients for the plurality of semiconductor die, providing one or more resistors on the semiconductor die, measuring, by a measurement circuit, a resistance of the one or more resistors on the semiconductor die at the first temperature, determining, by a control circuit, a calibrated temperature coefficient of the semiconductor die from the measured resistance of the one or more resistors on the semiconductor die at the first temperature and the RTCF, measuring, by the measurement circuit, the resistance of the one or more resistors on the semiconductor die at a second temperature, and determining, by the control circuit, the second temperature based on the resistance of the one or more resistors on the semiconductor die at the second temperature and the calibrated temperature coefficient of the semiconductor die.

In accordance with still further disclosed aspects, a semiconductor device includes a substrate that includes active devices, a resistor situated over the substrate and including at least two metal layers, a measurement circuit in the substrate and electrically connected to the resistor, the measurement circuit configured to measure resistance of the resistor at a first temperature, and a control circuit electrically connected to the measurement circuit and configured to determine a calibrated temperature coefficient of the resistor based on the measured resistance of the resistor at the first temperature and an RTCF.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of calibrating a temperature coefficient of a thermal sensor, the method comprising:
determining a resistance temperature coefficient function (RTCF) based on resistance measurements of resistors on a plurality of semiconductor die at a first temperature and temperature coefficients for the plurality of semiconductor die;
measuring, by a measurement circuit, a resistance of a resistor on a semiconductor die at the first temperature; and
determining, by a control circuit, a calibrated temperature coefficient of the semiconductor die based on the measured resistance of the resistor on the semiconductor die at the first temperature and the RTCF.

2. The method of claim 1, wherein determining the RTCF includes determining a linear approximation function of the resistance measurements at the first temperature and the temperature coefficients for the plurality of semiconductor die.

3. The method of claim 1, wherein determining the RTCF includes determining a linear approximation function of Wheatstone bridge resistance measurements at the first temperature and the temperature coefficients for the plurality of semiconductor die.

4. The method of claim 1, wherein determining the RTCF includes determining the RTCF at the first temperature of 25 degrees centigrade.

5. The method of claim 1, comprising:
determining a measured temperature coefficient of the semiconductor die for the measured resistance of the resistor on the semiconductor die at the first temperature; and
determining a ratio of the measured temperature coefficient of the semiconductor die to the calibrated temperature coefficient of the semiconductor die.

6. The method of claim 1, wherein the resistor on the semiconductor die includes a back-end-of-line (BEOL) resistor.

7. The method of claim 6, wherein the BEOL resistor includes at least two metal layers.

8. The method of claim 1, wherein measuring the resistance of the resistor on the semiconductor die includes providing a current from a current source through the resistor and measuring the resistance of the resistor on the semiconductor die in a single resistance measurement.

9. The method of claim 1, wherein measuring the resistance of the resistor on the semiconductor die includes measuring the resistance of the resistor in a Wheatstone bridge.

10. A method of measuring a temperature of a semiconductor die, comprising:
determining a resistance temperature coefficient function (RTCF) based on resistance measurements of resistors on a plurality of semiconductor die at a first temperature and temperature coefficients for the plurality of semiconductor die;
providing one or more resistors on the semiconductor die;
measuring, by a measurement circuit, a resistance of the one or more resistors on the semiconductor die at the first temperature;
determining, by a control circuit, a calibrated temperature coefficient of the semiconductor die from the measured resistance of the one or more resistors on the semiconductor die at the first temperature and the RTCF;
measuring, by the measurement circuit, the resistance of the one or more resistors on the semiconductor die at a second temperature; and
determining, by the control circuit, the second temperature based on the resistance of the one or more resistors on the semiconductor die at the second temperature and the calibrated temperature coefficient of the semiconductor die.

11. The method of claim 10, wherein determining the RTCF includes determining a linear approximation function of the resistance measurements at the first temperature and the temperature coefficients for the plurality of semiconductor die.

12. The method of claim 10, wherein determining the RTCF includes determining a linear approximation function of Wheatstone bridge resistance measurements at the first temperature and the temperature coefficients for the plurality of semiconductor die.

13. The method of claim 10, wherein the one or more resistors on the semiconductor die includes one or more back-end-of-line (BEOL) resistors.

14. The method of claim 10, wherein measuring the resistance of the one or more resistors on the semiconductor die includes providing a current from a current source through the one or more resistors and measuring the resistance of the one or more resistors on the semiconductor die in a single resistance measurement.

15. The method of claim 10, wherein measuring the resistance of the one or more resistors on the die includes measuring the resistance of the one or more resistors in a Wheatstone bridge.

16 A semiconductor device, comprising:
a substrate that includes active devices;
a resistor situated over the substrate and including at least two metal layers;
a measurement circuit in the substrate and electrically connected to the resistor,
the measurement circuit configured to measure resistance of the resistor at a first temperature; and
a control circuit electrically connected to the measurement circuit and configured to determine a calibrated temperature coefficient of the resistor based on the measured resistance of the resistor at the first temperature and a resistor temperature coefficient function (RTCF).

17. The device of claim 16, wherein the resistor is a back-end-of-line (BEOL) resistor.

18. The device of claim 16, wherein the measurement circuit includes a current source configured to provide current to the resistor to measure the resistance of the resistor in a single resistance measurement.

19. The device of claim 16, wherein the resistor is part of a Wheatstone bridge and the measurement circuit includes at least one voltage to frequency converter configured to measure the resistance of the resistor in the Wheatstone bridge.

20. The device of claim 16, wherein the measurement circuit is configured to measure the resistance of the resistor at a second temperature and the control circuit is configured to determine the second temperature based on the resistance of the resistor at the second temperature and the calibrated temperature coefficient.
